(19) United States
(12) Patent Application Publication
(10) Pub. No.: US 2015/0054173 A1
(43) Pub. Date: Feb. 26, 2015

(54) SEMICONDUCTOR PACKAGE, METHOD OF MANUFACTURING SEMICONDUCTOR PACKAGE AND STACK TYPE SEMICONDUCTOR PACKAGE

(71) Applicant: SAMSUNG ELECTRO-MECHANICS CO., LTD., Suwon-Si (KR)

(72) Inventors: Tae Hyun KIM, Suwon-Si (KR); Do Jae YOO, Suwon-si (KR); Heung Woo PARK, Suwon-si (KR)

(73) Assignee: SAMSUNG ELECTRO-MECHANICS CO., LTD., Suwon-Si (KR)

(21) Appl. No.: 14/328,672

(22) Filed: Jul. 10, 2014

(30) Foreign Application Priority Data
Aug. 20, 2013 (KR) 10-2013-0098372

(51) Int. Cl. H01L 23/522; H01L 23/31; H01L 21/50; H01L 21/56

(52) U.S. Cl. CPC H01L 23/5226; H01L 21/565; H01L 23/3107; H01L 21/50; H01L 2021/6027
USPC 257/774; 438/124

(57) ABSTRACT

Disclosed herein are a semiconductor package, a method of manufacturing a semiconductor package, and a stack type semiconductor package. The semiconductor package according to a preferred embodiment of the present invention includes: a base substrate on which a first circuit layer is formed; a semiconductor device formed on the base substrate; a molding part formed on the base substrate and formed to enclose the first circuit layer and the semiconductor device; a first via formed on the first circuit layer and formed to penetrate through the molding part; and a second circuit layer formed on an upper surface of the molding part and integrally formed with the first via.

### CROSS REFERENCE TO RELATED APPLICATION

This application claims the benefit of Korean Patent Application No. 10-2013-0098372, filed on Aug. 20, 2013, entitled “Semiconductor Package, Method of Manufacturing Semiconductor Package, and Stack Type Semiconductor Package”, which is hereby incorporated by reference in its entirety into this application.

### BACKGROUND OF TEE INVENTION

1. Technical Field

The present invention relates to a semiconductor package, a method of manufacturing a semiconductor package, and a stack type semiconductor package.

2. Description of the Related Art

In accordance with the rapid development of a semiconductor technology, a semiconductor device has significantly grown. Further, the development for a semiconductor package, such as a system in package (SIP), a chip sized package (CSP), and a flip chip package (FCP) which are configured as a package by mounting an electronic device, such as the semiconductor device, on a printed circuit board in advance has been actively conducted. In the semiconductor package, the semiconductor device is mounted on the printed circuit board and is subjected to a molding, and then a via is formed in a molding material. In this case, a via hole for forming the via is machined using a laser (U.S. Pat. No. 8,354,744). In the case of the laser machining, when a plurality of via holes are machined, the via holes may not simultaneously machined, but needs to be individually machined.

### SUMMARY OF THE INVENTION

The present invention has been made in an effort to provide a semiconductor package which does not need to perform laser machining for forming a via hole, a method of manufacturing a semiconductor package, and a stack type semiconductor package.

Further, the present invention has been made in an effort to provide a semiconductor package in which a plurality of vias are formed simultaneously formed, a method of manufacturing a semiconductor package, and a stack type semiconductor package.

In addition, the present invention has been made in an effort to provide a semiconductor package with the improved degree of freedom in design, a method of manufacturing a semiconductor package, and a stack type semiconductor package.

According to a preferred embodiment of the present invention, there is provided a semiconductor package, including: a base substrate on which a first circuit layer is formed; a semiconductor device formed on the base substrate; a molding part formed on the base substrate and formed to enclose the first circuit layer and the semiconductor device; a first via formed on the first circuit layer and formed to penetrate through the molding part; and a second circuit layer formed on an upper surface of the molding part and integrally formed with the first via.

A lower surface of the first via may have a diameter larger than that of an upper surface thereof.

A lower surface of the first via may have a diameter smaller than that of an upper surface thereof.

The first via may be bent once or more so that a center of the upper surface thereof and a center of the lower surface thereof are disposed on different vertical lines.

The first via may be bent once or more so that a center of the upper surface thereof and a center of the lower surface thereof are disposed on the same vertical line.

The first via may include at least one of a conductive metal and a conductive resin.

An inside of the first via may be made of a non-conductive resin.

An adhesive layer may be further formed between the first via and the first circuit layer.

The adhesive layer may include at least one of a low-melting metal and a temporarily cured conductive epoxy resin.

The semiconductor device may be connected to the first circuit layer by a wire.

The semiconductor package may further include: a second via of which the lower surface is connected to the semiconductor device and the upper surface is connected to the second circuit layer.

The second circuit layer may electrically connect the first via to the second via.

The second via may be made of the same material as the first via.

The semiconductor package may further include: an external connection terminal formed on the second circuit layer.

According to another preferred embodiment of the present invention, there is provided a method of manufacturing a semiconductor package, including: preparing a base substrate on which a first circuit layer and a semiconductor device are formed; preparing a frame having a lower surface provided with a first via; mounting the frame on the base substrate; forming a molding part by injecting a molding material between the base substrate and the frame; and forming a second circuit layer by patterning the frame.

The preparing of the frame having the lower surface provided with the first via may include: preparing the frame; and forming the first via on the frame by injecting a conductive resin into the frame by a screen printing method or an injection molding method.

The preparing of the frame having the lower surface provided with the first via may include: preparing the frame; forming an inside of the first via on the frame by injecting a non-conductive resin into the frame by a screen printing method or an injection molding method; and forming the first via by plating a conductive material to the inside of the first via.

The preparing of the frame having the lower surface provided with the first via may include: preparing the frame; and forming the first via by providing plastic deformation of one side of the frame with a press mold.

The number of frames may be plural.

A lower surface of the first via may have a diameter larger than that of an upper surface thereof.

A lower surface of the first via may have a diameter smaller than that of an upper surface thereof.

The first via may be bent once or more so that a center of the upper surface thereof and a center of the lower surface thereof are disposed on different vertical lines.

The first via may be bent once or more so that a center of the upper surface thereof and a center of the lower surface thereof are disposed on the same vertical line.

The preparing of the frame having the lower surface provided with the first via may include applying an adhesive on a lower surface of the first via.

The adhesive may include at least one of a low-melting metal and a temporarily cured conductive epoxy.

The semiconductor device may be connected to the first circuit layer by a wire.

The preparing of the frame having the lower surface provided with the first via may include forming a second via connected to the semiconductor device.

The second via may be formed by the same material and method as the first via.

The second circuit layer may electrically connect the first via to the second via.

The method of manufacturing a semiconductor package may further include: after the forming of the second circuit layer, forming an external connection terminal to the second circuit layer.

According to still another preferred embodiment of the present invention, there is provided a stack type semiconductor package, including: a first semiconductor package which includes a base substrate on which a first circuit layer and a first semiconductor device are formed, a molding part formed on the base substrate and formed to enclose the first circuit layer and the first semiconductor device, a first via formed on the first circuit layer and formed to penetrate through the molding part, and a second circuit layer formed on an upper surface of the molding part and integrally formed with the first via; and a second semiconductor package formed on the first semiconductor package and including a second semiconductor device.

A lower surface of the first via may have a diameter larger than that of an upper surface thereof.

A lower surface of the first via may have a diameter smaller than that of an upper surface thereof.

The first via may be bent once or more so that a center of the upper surface thereof and a center of the lower surface thereof are disposed on different vertical lines.

The first via may be bent once or more so that a center of the upper surface thereof and a center of the lower surface thereof are disposed on the same vertical line.

The first semiconductor package may be connected to the second semiconductor package by an external connection terminal.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified diagram illustrating a semiconductor package according to a first preferred embodiment of the present invention;

FIGS. 2 to 8 are exemplified diagrams illustrating a method of manufacturing a semiconductor package according to the first embodiment of the present invention;

FIGS. 9 to 12 are exemplified diagrams illustrating a method of forming a first via in a frame according to another preferred embodiment of the present invention;

FIG. 13 is an exemplified diagram illustrating a semiconductor package according to a second preferred embodiment of the present invention;

FIG. 14 is an exemplified diagram illustrating a semiconductor package according to a third preferred embodiment of the present invention;

FIGS. 15 to 18 are exemplified diagrams illustrating a semiconductor package and a method of manufacturing a semiconductor package according to a fourth preferred embodiment of the present invention;

FIGS. 19 to 21 are exemplified diagrams illustrating various preferred embodiments of a frame; and

FIG. 22 is an exemplified diagram illustrating a stack type semiconductor package according to still another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

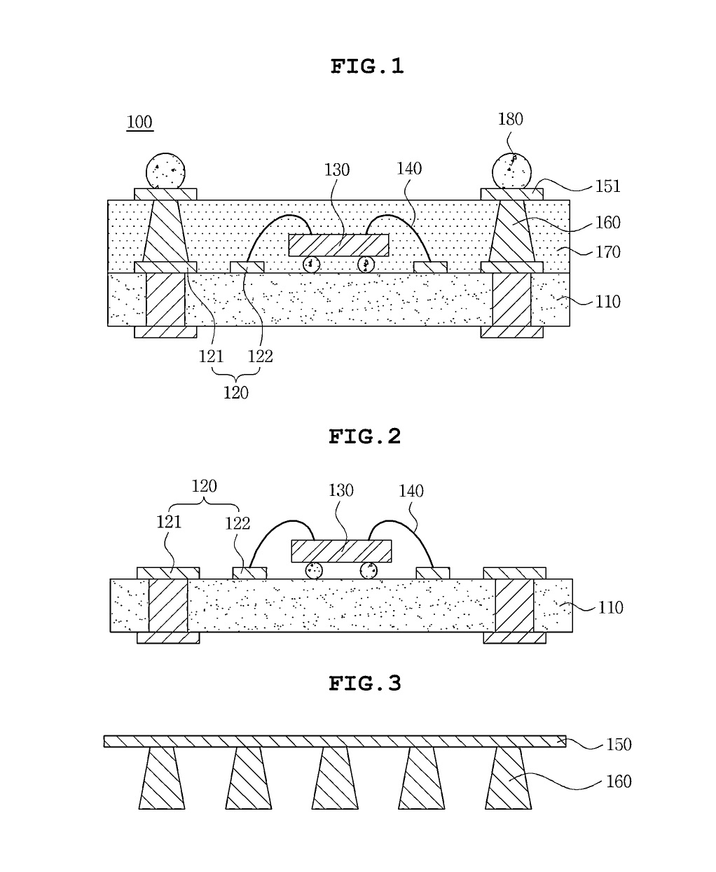

FIG. 1 is an exemplified diagram illustrating a semiconductor package according to a first preferred embodiment of the present invention.

Referring to FIG. 1, a semiconductor package 100 may include a base substrate 110, a first circuit layer 120, a semiconductor device 130, a molding part 170, a via 160, a second circuit layer 151, and an external connection terminal 180.

The base substrate 110 may be a printed circuit board which includes an insulating layer and a circuit layer. FIG. 1 illustrates that the base substrate 110 is formed in an insulating layer and a circuit layer (via) of a single layer, but the preferred embodiment of the present invention is not limited thereto. That is, an inside of the base substrate 110 may be provided with a circuit layer and insulating layer of at least one layer. Herein, the insulating layer may be made of a thermosetting resin, such as epoxy resin and a thermoplastic resin, such as polyimide. Alternatively, the insulating layer may be made of resin in which reinforcing materials, such as a glass fiber and an inorganic filter, are impregnated in the epoxy resin. For example, the reinforcing material may be prepreg. Alternatively, the insulating layer may be made of a photocurable resin, and the like. However, the material of the insulating layer is not particularly limited. As the material of the circuit layer, any material which is used as a conductive material for a circuit in a circuit substrate field may be applied without being limited and may be generally made of copper.

In addition, the base substrate 110 may be a ceramic substrate. The ceramic substrate may be made of metal-based nitride and a ceramic material. For example, the metal-based nitride may include aluminum nitride (AIN) or silicon nitride (SiN). Further, the ceramic material may include aluminum oxide (Al₂O₃) or beryllium oxide (BeO). A kind of metal-based nitride and ceramic material is by way of example and therefore the material of the ceramic substrate is not limited thereto.

In addition, the base substrate 110 may be a metal substrate. For example, the metal substrate may be made of aluminum (Al) or an aluminum alloy which has excellent heat transfer characteristics. The metal substrate made of aluminum or aluminum alloy may be provided with an insulating layer using an anodizing method. The insulating layer formed by the anodizing method may be an aluminum anodizing layer (Al₂O₃). Since the anodizing layer has insulation, the circuit layer may be formed on the metal substrate. Further, the circuit layer may be formed at a thickness smaller than that of the general insulating layer, heat radiation performance may be improved and thinness may be realized. The material of the metal substrate is not limited to aluminum and aluminum alloy, and therefore may include manganese (Mg), zinc (Zn), titanium (Ti), hafnium (Hf), and the like, to which the anodizing method may be applied.

The first circuit layer 120 may be formed on the base substrate 110. The first circuit layer 120 may be made of a conductive material. For example, the first circuit layer 120 may be made of copper. However, the material of the first circuit layer 120 is not limited to copper, and therefore any material which is used as a conductive material for a circuit in the circuit substrate field may be applied without being limited.

According to the preferred embodiment of the present invention, the first circuit layer 120 may include a first connection pad 121 and a second connection pad 122. The first connection pad 121 may be connected to the via 160. The second connection pad 122 may be connected to the semiconductor device 130 by a wire. Further, the first circuit layer 120 is not illustrated, but may further include a circuit pattern.

The semiconductor device 130 may be mounted on the base substrate 110. The semiconductor device 130 may be at least any one of a power device and a control device. For example, the power device may be an insulated gate bipolar transistor (IGBT), a diode, and the like. The control device may be a control integrated circuit (IC). This is an example and a kind of the semiconductor device 130 mounted in the semiconductor package 100 is not limited thereto. FIG. 1 illustrates a single semiconductor device, but a plurality of semiconductor devices may be mounted.

The molding part 170 may be formed on the base substrate 110 to enclose the first circuit layer 120 and the semiconductor device 130. The molding part 170 may protect the first circuit layer 120 and the semiconductor device 130 from external environment. The molding part 170 may be generally made of a silicon gel or an epoxy molded compound (EMC).

The via 160 is formed on the first circuit layer 120 and may be formed to penetrate through the molding part 170. The via 160 is formed on the first connection pad 121 of the first circuit layer 120 to be able to electrically connect the first circuit layer 120 to the second circuit layer 151. That is, a lower surface of the via 160 may be connected to the first connection pad 121 and an upper surface thereof may be connected to the second circuit layer 151. According to the preferred embodiment of the present invention, the via 160 may be formed so that the lower surface thereof has a diameter larger than that of the upper surface thereof. The reason is that the via 160 is formed on the frame (not illustrated) in advance and is then mounted on the base substrate 110. The via 160 is formed so that the lower surface thereof has a diameter larger than that of the upper surface thereof, such that the via 160 may be stably mounted on the base substrate 110 and the matching degree with the first circuit layer 120 may be improved. Further, although not illustrated in another preferred embodiment, the via 160 may be formed so that the lower surface of the via has a diameter smaller than that of the upper surface thereof. When the via 160 is formed so that the upper surface thereof has a diameter larger than that of the lower surface thereof, the matching degree with the second circuit layer 151 may be increased. That is, when the second circuit layer 151 is formed, the second circuit layer 151 may be sufficiently bonded to the via 160 even when there is a position error of the second circuit layer 151.

A method of forming the via 160 will be described in detail below. The via 160 may be made of a conductive metal or a conductive resin. Further, an inside of the via 160 is made of a non-conductive resin and an outside thereof may be made of a conductive metal or a conductive resin. When the conductive metal, the conductive resin, and the non-conductive resin forming the via 160 may be used in the circuit substrate field, any material may be applied without being limited.

The second circuit layer 151 may be formed on an upper surface of the molding part 170. The second circuit layer 151 may be integrally formed with the via 160. The second circuit layer 151 may be formed by mounting the via 160 formed in the frame (not illustrated) on the substrate 110 and patterning the frame (not illustrated). The second circuit layer 151 may be made of a conductive material. For example, the second circuit layer 151 may be made of copper. However, the material of the second circuit layer 151 is not limited to copper, and therefore any material which may be used as a conductive material for a circuit in the circuit substrate field may be applied without being limited.

The second circuit layer 151 may include an external connection pad. Although not illustrated, the external connection pad may be provided with a surface treatment layer, if necessary. The surface treatment layer (not illustrated) may be formed to prevent an oxide layer from being formed on a surface of the external connection pad. Any surface treatment layer (not illustrated) which is known to those skilled in the art may be used without being limited.

The second circuit layer 151 may further include a circuit pattern (not illustrated). When the second circuit layer 151 includes the circuit pattern (not illustrated), the circuit pattern (not illustrated) is buried and a solder resist (not illustrated) formed with an opening through which the external connection pad is exposed may be further formed.

The external connection terminal 180 may be formed on the external connection pad of the second circuit layer 151. The external connection terminal 180 may electrically connect the semiconductor package 100 to external components (not illustrated). Herein, the external components (not illustrated) may be another semiconductor package, semiconductor device, substrate, and the like. The external connection terminal 180 may be made of a conductive material which is used in a circuit substrate field. For example, the external connection terminal 180 may be a solder ball, a solder bump, a metal post, and the like.

Although not illustrated in FIG. 1, an adhesive layer (not illustrated) may be further formed between the via 160 and the first connection pad 121.

FIGS. 2 to 8 are exemplified diagrams illustrating a method of manufacturing a semiconductor package according to the first embodiment of the present invention.

Referring to FIG. 2, the base substrate 110 on which the semiconductor device 130 is mounted is provided.

The base substrate 110 may be a printed circuit board, a ceramic substrate, or a metal substrate. Although not illustrated, the inside of the base substrate 110 may be provided with a circuit layer and insulating layer of at least one layer. The base substrate 110 may be provided with the first circuit layer 120. The first circuit layer 120 may be made of a conductive material. The first circuit layer 120 may include the first connection pad 121 and the second connection pad 122. Further, the first circuit layer 120 is not illustrated, but may further include the circuit pattern. The first connection pad 121 may be connected to the via 160. Further, the second connection pad 122 may be connected to the wire 140. Herein, the wire 140 may electrically connect the second connection pad 122 to the semiconductor device 130.

The semiconductor device 130 may be at least any one of the power device and the control device. FIG. 2 illustrates one semiconductor device 130, but the base substrate 110 may have a plurality of semiconductor devices mounted thereon. According to the preferred embodiment of the present invention, the semiconductor device 130 may be mounted on the base substrate 110 by the solder ball. Further, the semiconductor device 130 may be electrically connected to the base substrate 110 by the solder ball. The semiconductor device 130 may be mounted on the base substrate 110 by the solder ball, the solder bump, a conductive adhesive, or a non-conductive adhesive. According to the preferred embodiment of the present invention, the semiconductor device 130 may be electrically connected to the first circuit layer 120 by a wire bonding.

Referring to FIG. 3, the frame 150 formed with the via 160 may be prepared. The via 160 and the frame 150 may be integrally formed. The frame 150 may be made of a conductive metal or a conductive resin. For example, the frame 150 may be made of copper. However, the material of the frame 150 is not limited to copper, and therefore any material which may be used as a conductive material for a circuit in the circuit substrate field may be applied without being limited. The via 160 is formed on the lower surface of the frame 150. The via 160 may be made of a conductive metal or a conductive resin. Further, the inside of the via 160 is made of the non-conductive resin and the outside thereof may be made of a conductive metal or a conductive resin. Further, the adhesive layer (not illustrated) may be formed by applying an adhesive on the lower surface of the via 160.

The via 160 may be formed so that the lower surface thereof has a diameter larger than that of the upper surface thereof.

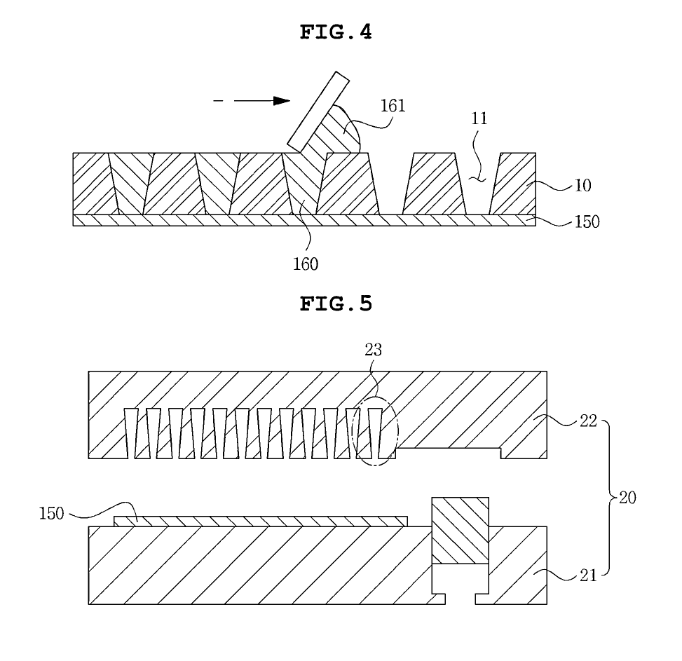

The via 160 may be formed on the frame 150 by the method illustrated in FIGS. 4 and 5.

Referring to FIG. 4, the via 160 may be formed by a screen printing method. One surface of the frame 150 may be provided with a mask 10 on which the opening 11 is formed. A shape of the opening 11 may correspond to a shape of the via 160. The via 160 may be formed on one surface of the frame 150 by filling the opening 11 of the mask 10 with a conductive metal or a conductive resin using a squeegee. When the via 160 is formed on the frame 150, the mask 10 may be removed.

Referring to FIG. 5, the via 160 may be formed by an injection molding method. The injection molding method may be performed using an injection mold 20. The injection mold 20 may include a lower mold 21 and an upper mold 22. The frame 150 may be mounted on the lower mold 21. The upper mold 22 may be provided with a frame 23. Herein, the frame 23 may have a shape of the via 160. One surface of the frame 150 mounted on the lower mold 21 is provided with the frame 23 into which a conductive resin 161 may be injected. Next, the one surface of the frame 150 may be provided with the via 160 by a holding pressure process, a cooling process, and the like.

In FIGS. 4 and 5, the one surface of the frame 150 may be a lower surface. Further, the case in which the via 160 is made of a conductive metal or a conductive resin, but the preferred embodiment of the present invention is not limited thereto. For example, in FIG. 4, the inside of the via 160 may be formed by filling the opening 11 of the mask 10 with the non-conductive resin. Further, in FIG. 5, the inside of the via 160 may be formed by injecting the non-conductive resin into the frame 23. Next, the via 160 may be formed by plating the inside of the via made of the non-conductive resin with a conductive metal or applying the inside thereof with a conductive resin.

Although not illustrated in the preferred embodiment of the present invention, the adhesive layer (not illustrated) may be formed by forming the via 160 on the frame 150 and then applying the adhesive on the lower surface of the via 160. In this case, the adhesive may include at least one of a low-melting point metal and a temporarily cured conductive epoxy.

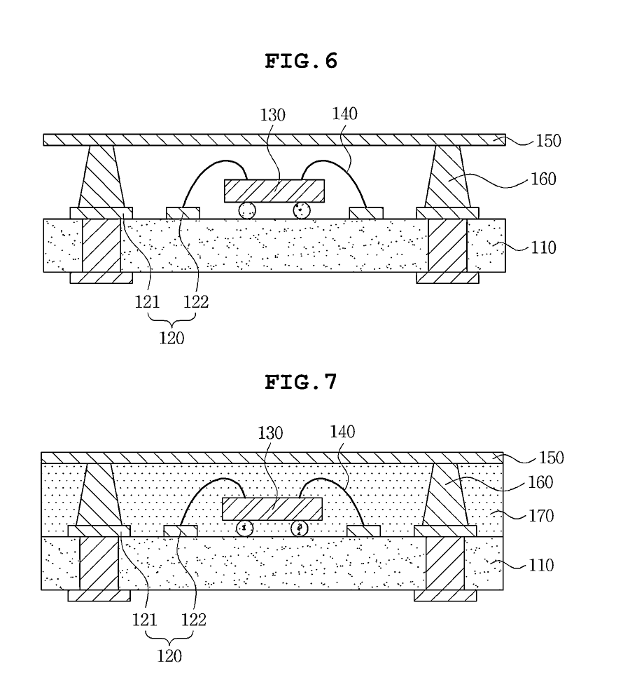

Referring to FIG. 6, the frame 150 may be mounted on the base substrate 110. In this case, the via 160 may be disposed on the first circuit layer 120 to be connected to the first circuit layer 120. In this case, the via 160 may be mounted on the first connection pad 121 of the first circuit layer 120 to be electrically connected to the first connection pad 121. The via 160 is formed so that the lower surface thereof has a diameter larger than that of the upper surface thereof, and thus may be stably mounted on the base substrate 110. Further, the matching degree with the first connection pad 121 may be improved by the lower surface of the via 160 having a larger diameter.

The preferred embodiment of the present invention describes by way of example that the upper surface of the via 160 has a diameter larger than that of the lower surface thereof, but the structure of the via 160 is not limited thereto. Although not illustrated, according to another preferred embodiment of the present invention, the via 160 is formed so that the upper surface thereof has a diameter smaller than that of the lower surface thereof, thereby improving the matching degree with the second circuit layer (not illustrated) which is formed later.

Referring to FIG. 7, the molding part 170 may be formed. The molding part 170 may be formed by filling a molding material between the base substrate 110 and the frame 150. The molding part 170 may be made of a silicon gel or an epoxy molding compound. The so formed molding part 170 may protect the first circuit layer 120 and the semiconductor device 130 from external environment.

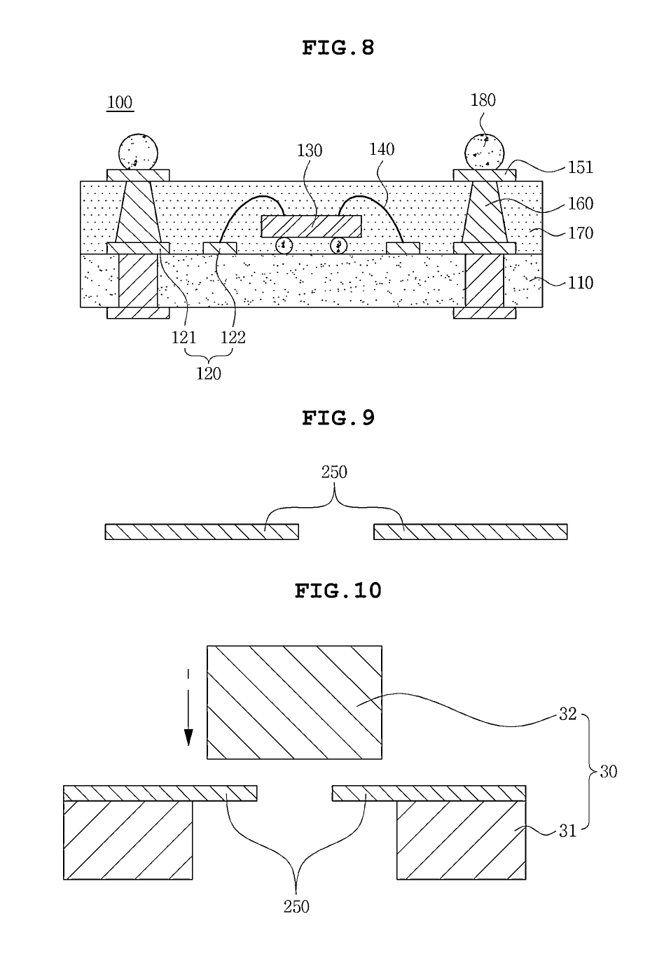

Referring to FIG. 8, the second circuit layer 151 may be formed on an upper surface of the molding part 170. The second circuit layer 151 may be formed by patterning the frame 150. The second circuit layer 151 may be formed by forming an etching resist (not illustrated) protecting a region, in which the second circuit layer 151 is formed, on the frame 150 and performing etching. The second circuit layer 151 is formed using the frame 150 which is integrated with the via 160 and thus the via 160 and the second circuit layer 151 may also be integrated. The second circuit layer 151 may include the external connection pad.

Although not illustrated in the preferred embodiment of the present invention, the surface of the external connection pad may be provided with the surface treatment layer, if necessary. Any material of the surface treatment layer (not illustrated) and any method of forming the surface treatment layer that are known to those skilled in the art are not particularly limited.

Although the second circuit layer 151 is not illustrated, the second circuit layer 151 may further include the circuit pattern (not illustrated). When the second circuit layer 151 includes the circuit pattern (not illustrated), the circuit pattern (not illustrated) is buried and the solder resist (not illustrated) having a structure in which the external connection pad is exposed may be further formed.

Next, the external connection pad of the second circuit layer 151 may be provided with the external connection terminal 180. Herein, the external connection terminal 180 is a component which electrically connects the semiconductor package 100 to external components (not illustrated). The external connection terminal 180 may be a solder ball, a solder bump, a metal post, and the like.

FIGS. 9 to 12 are exemplified diagrams illustrating a method of forming a via in a frame according to another preferred embodiment of the present invention.

Referring to FIG. 9, a frame 250 may be prepared. The frame 250 may be made of a conductive metal. According to the preferred embodiment of the present invention, the number of frames 250 is two, but is not limited thereto. That is, if necessary, the number of frames 250 may be one and may be plural.

Referring to FIG. 10, the frame 250 may be mounted in a press mold 30. The press mold 30 may include a die 31 and a punch 32. The punch 32 may be molded as a via 260 by bending a part of the frame 250 by applying a pressure to the frame 250. The die 31 may be mounted with the frame 250. The die 31 may be provided with a punch insertion part 33 into which the punch 32 is inserted. The via 260 may be molded in another shape depending on a shape of the punch insertion part 33. According to the preferred embodiment of the present invention, the punch insertion part 33 may be formed in a quadrangular shape.

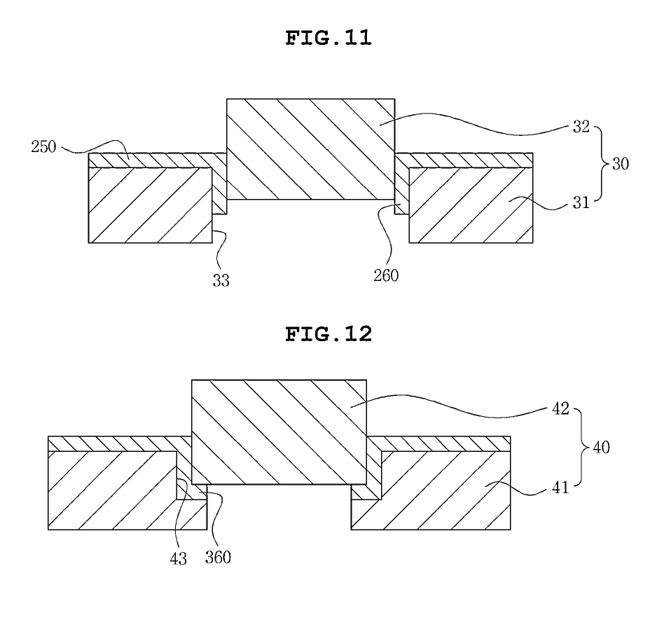

Referring to FIG. 11, the via 260 may be formed. A portion of the frame 250 may be molded as the via 260 by pressing the frame 250 mounted in the press mold 30 with the punch 32. In this case, a part of the frame 250 may be bent along an inner wall of the punch insertion part 33 of the die 31. A part of the frame 250 which is bent along the inner wall of the punch insertion part 33 may be the via 260. The so formed via 260 may be formed so that the upper and lower surfaces thereof have the same diameter. Further, the via 260 may be formed so that the upper and lower surfaces thereof have different diameters, by using the frame 250 of which the one end and the other end have different diameters.

A method of forming a via 360 using a press mold 40 according to another preferred embodiment of the present invention will be described with reference to FIG. 12. Herein, a punch insertion part 43 may be formed so that an inner wall thereof has a step. Therefore, the via 360 may be formed in a shape bent along the step of the inner wall of the punch insertion part 43. That is, the via 360 is formed by bending a part of the frame 350 and at the same time, the via 360 itself may be formed so as to be bent.

The via formed as illustrated in FIGS. 9 to 12 is formed by molding a part of the frame and is integrally formed with the frame.

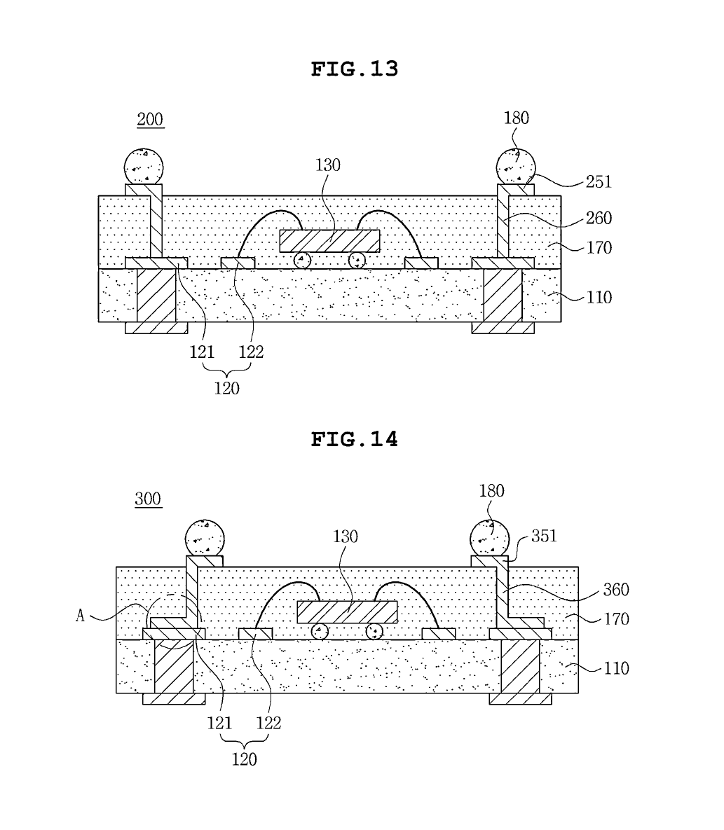

FIG. 13 is an exemplified diagram illustrating a semiconductor package according to a second preferred embodiment of the present invention.

Referring to FIG. 13, a semiconductor package 200 may have a structure in which the frame 250 formed with the via 260 is mounted on the base substrate 110.

The base substrate 110 may be provided with the first circuit layer 120 and the semiconductor device 130. The first circuit layer 120 may include the first connection pad 121 and the second connection pad 122. The first connection pad 121 may be electrically connected to the via 260. The second connection pad 122 may be wire-bonded with the semiconductor device 130.

The base substrate 110 may be provided with the molding part 170 which encloses the first circuit layer 120, the semiconductor device 130, and the via 260.

The upper surface of the molding part 170 may be provided with a second circuit layer 251. The second circuit layer 251 may be the external connection pad. The second circuit layer 251 may be formed by patterning the frame 250 of FIG. 11. That is, in FIG. 11, since the via 260 and the frame 250 are integrated, the second circuit layer 251 may also be integrally formed with the via 260.

The external connection pad of the second circuit layer 251 may be provided with the external connection terminal 180 such as a solder ball.

FIG. 14 is an exemplified diagram illustrating a semiconductor package according to a third preferred embodiment of the present invention.

Referring to FIG. 14, a semiconductor package 300 may have a structure in which the frame 350 formed with the via 360 of FIG. 12 is mounted on the base substrate 110. In this case, a cross section of the frame 350 may be directed to a vertical line of a center of the semiconductor package 300.

The base substrate 110 may be provided with the first circuit layer 120 and the semiconductor device 130. The first circuit layer 120 may include the first connection pad 121 and the second connection pad 122. The first connection pad 121 may be connected to the via 360. In this case, a portion A at which the via 360 is bent may be bonded to the first connection pad 121. Therefore, a bonded area between the via 360 and the first connection pad 121 is increased, such that the via 360 is stably bonded to the first connection pad 121. The second connection pad 122 may be wire-bonded with the semiconductor device 130.

The base substrate 110 may be provided with the molding part 170 which encloses the first circuit layer 120, the semiconductor device 130, and the via 360.

The upper surface of the molding part 170 may be provided with a second circuit layer 351. The second circuit layer 351 may be the external connection pad. The second circuit layer 351 may be formed by patterning the frame 350 of FIG. 12. That is, in FIG. 12, since the via 360 and the frame 350 are integrated, the second circuit layer 351 may also be integrally formed with the via 360.

According to the preferred embodiment of the present invention, the second circuit layer 351 may be disposed on the upper surface of the via 360 or on a vertical line at which the center of the second circuit layer 351 and the center of the lower surface of the via 360 are different from each other. That is, a position at which the second circuit layer 351 is formed may be freely changed depending on a shape of the via 360. Therefore, a degree of freedom in design of the semiconductor package may be improved.

Further, although not illustrated in the preferred embodiment of the present invention, the second circuit layer 351 may be disposed on the upper surface of the via 360 or on a vertical line at which the center of the second circuit layer 351 and the center of the lower surface of the via 360 are the same. In this case, even though the upper and lower surfaces of the via 360 are the same vertical line, a body of the via 360 may be variously bent, thereby improving the degree of freedom in design of components in the semiconductor package 300.

The external connection pad of the second circuit layer 351 may be provided with the external connection terminal 180 such as a solder ball.

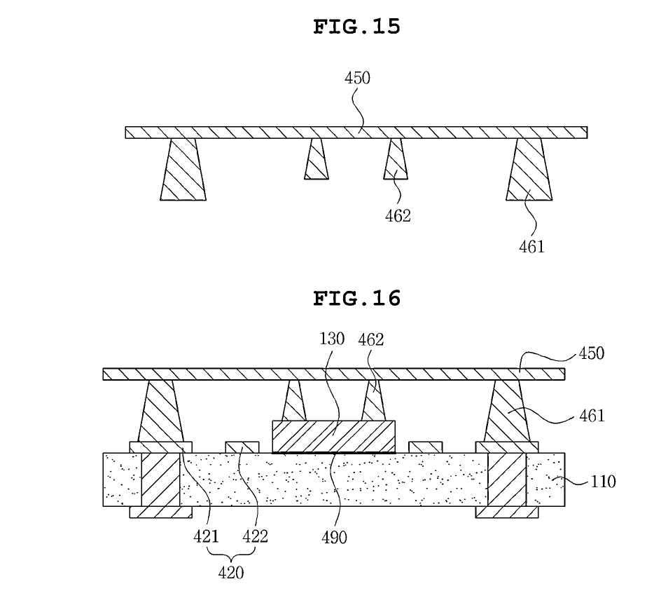

FIGS. 15 to 18 are exemplified diagrams illustrating a semiconductor package and a method of manufacturing a semiconductor package according to a fourth preferred embodiment of the present invention.

Referring to FIG. 15, a frame 450 including a first via 461 and a second via 462 may be prepared. The first via 461 and the second via 462 may be formed to have different heights. The first via 461 may be formed to have a height so as to be bonded to a first circuit layer (420 of FIG. 16) of the base substrate (110 of FIG. 16). The second via 462 may have a height so as to be bonded to the semiconductor device (130 of FIG. 16). That is, the first via 461 and the second via 462 may be formed to have different heights depending on the position and thickness of components which are bonded to each other. The material of the frame 450 and the first via 461 and the method for forming the frame 450 and the first via 461 may be the same as the method for forming the first via in the frame as described above. The second via 462 may be formed by the same material and method as the first via 461. Further, the second via 462 may be simultaneously formed with the first via 461 or may be separately formed therefrom. The first via 461 and the second via 462 are integrally on the frame 450 and then may be mounted on the base substrate (110 of FIG. 16).

Although not illustrated in the preferred embodiment of the present invention, the adhesive layer (not illustrated) may be formed by forming the first via 461 and the second via 462 on the frame 450 and then applying an adhesive on the lower surfaces of the first via 461 and the second via 462. In this case, the adhesive may be made of a conductive material. For example, the adhesive may include at least one of a low-melting point metal and a temporarily cured conductive epoxy.

Referring to FIG. 16, the frame 450 formed with the first via 461 and the second via 462 may be mounted on the base substrate 110.

The base substrate 110 may be provided with the first circuit layer 420 and the semiconductor device 130. The first circuit layer 420 may include the connection pad 421. Further, the first circuit layer 420 may further include the circuit pattern 422. The lower surface of the semiconductor device 130 may be applied with an adhesive 490 to be well adhered to the base substrate 110. Herein, the adhesive 490 may be a conductive resin or a non-conductive resin.

When the frame 450 is mounted on the base substrate 110, the firs via 461 may be bonded to the connection pad 421. Further, the second via 462 may be bonded to the semiconductor device 130. In this case, although not illustrated, the second via 462 may be bonded to an electrode of the semiconductor device 130.

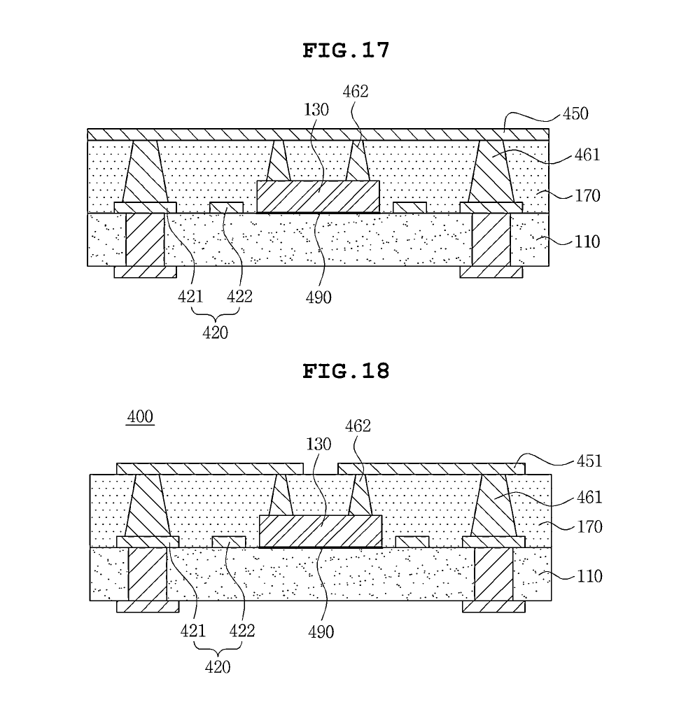

Referring to FIG. 17, the molding part 170 may be formed. The molding part 170 may be formed by filling a molding material between the base substrate 110 and the frame 450. The molding part 170 may be made of a silicon gel or an epoxy molding compound. The so formed molding part 170 may protect the first circuit layer 420 and the semiconductor device 130 from external environment.

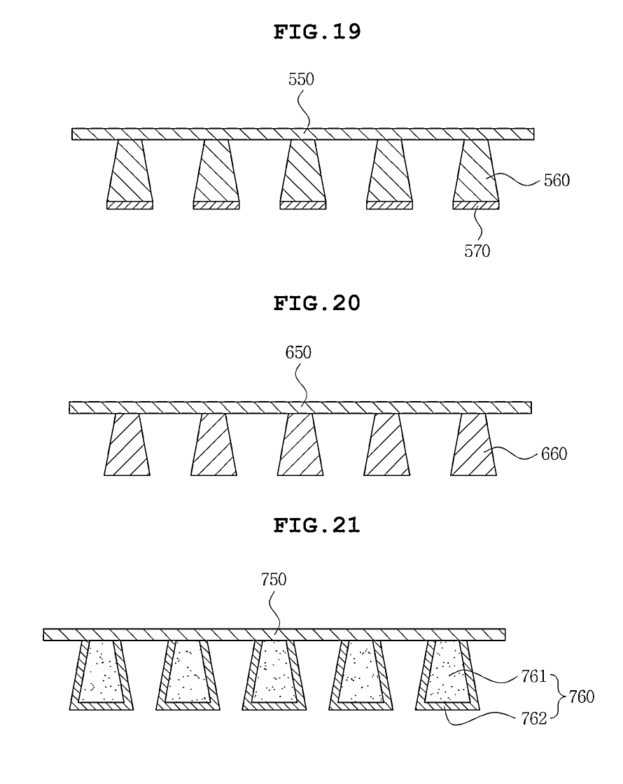

Referring to FIG. 18, the second circuit layer 451 may be formed on an upper surface of the molding part 170. The second circuit layer 451 may be formed by patterning the frame 450. That is, a lower surface of the first via 461 may be bonded to the first circuit layer 420 and an upper surface thereof may be bonded to the second circuit layer 451. Further, a lower surface of the second via 462 may be bonded to the semiconductor device 130 and an upper surface thereof may be bonded to the second circuit layer 451. The second circuit layer 451 may be formed by forming an etching resist (not illustrated) protecting the region in which the second circuit layer 452 is formed on the frame 450 and performing etching. The second circuit layer 450 is formed using the frame 450 which is integrated with the first via 461 and thus the first via 461 and the second circuit layer 451 may also be integrated.

A semiconductor package 400 according to a preferred embodiment of the present invention may have a structure in which the second circuit layer 451 is simultaneously bonded to the first via 461 and the second via 462. Therefore, the semiconductor device 130 may be electrically connected to the first circuit layer 420 through the second circuit layer 451.

The second circuit layer 451 may include the external connection pad. Although not illustrated in the preferred embodiment of the present invention, the external connection pad (not illustrated) may be mounted on the external connection terminal (not illustrated), such as a solder ball and a solder bump, and the like.

FIGS. 19 to 21 are exemplified diagrams illustrating various preferred embodiments of a frame.

Referring to FIG. 19, a via 560 may be formed on a frame 550. The frame 550 may be made of a conductive metal or a conductive resin. The via 560 formed on the lower surface of the frame 550 may be made of a conductive metal. In addition, a lower surface of the via 560 may be provided with an adhesive layer 570. The adhesive layer 570 may include at least one of a low-melting point metal and a temporarily cured conductive epoxy resin.

Referring to FIG. 20, the frame 650 may be made of a conductive metal or a conductive resin. The via 660 formed on the lower surface of the frame 650 may be made of a conductive resin.

Referring to FIG. 21, a frame 750 may be made of a conductive metal or a conductive resin. An inside 761 of the via 760 formed on the lower surface of the frame 750 may be made of a non-conductive resin. Further, an outside 762 of the via 760 may be made of a conductive resin or a conductive metal. The via 760 according to the preferred embodiment of the present invention may be formed by coating or plating a conductive resin or a conductive metal on the surface of the inside 761 made of a non-conductive resin.

The via illustrated in FIGS. 19 to 21 are integrally formed on the frame in advance, prior to being mounted on the base substrate. Further, the upper surface bonded to the frame may be formed to have a diameter smaller than the lower surface. When the diameter of the lower surface of the via is formed to be larger than that of the upper surface thereof, the via may stably be mounted on the base substrate. Further, since the lower surface of the via has a large area which may be bonded to the circuit layer, the adhesion and the matching degree may be improved. Further, although not illustrated, the upper surface of the via according to another preferred embodiment of the present invention has a diameter smaller than the lower surface thereof, such that the matching degree with the second circuit layer formed by patterning the frame later may be improved.

In FIGS. 19 to 21, the via may be formed by a screen printing method or an injection molding method. However, the structure of the via formed in the frame is not limited thereto. As illustrated in FIGS. 9 to 12 as described above, the via may be formed using the press mold. The via may be integrally formed with the frame even the case of using the press mold.

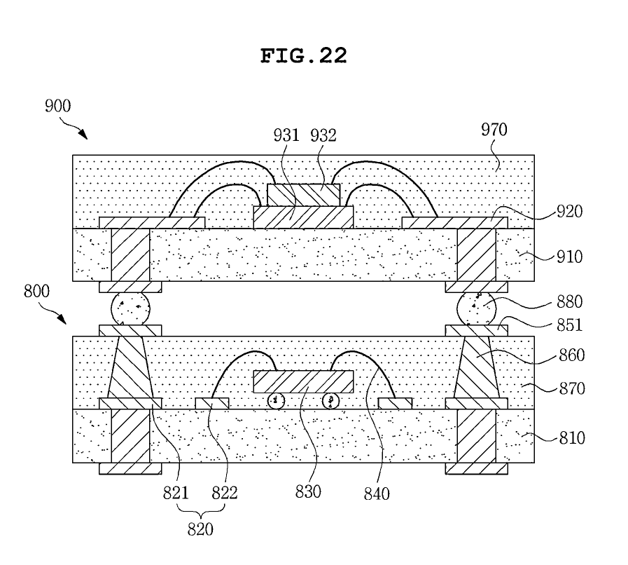

FIG. 22 is an exemplified diagram illustrating a stack type semiconductor package according to still another preferred embodiment of the present invention.

Referring to FIG. 22, a stack type semiconductor package 1000 includes a first semiconductor package 800 and a second semiconductor package 900.

The first semiconductor package 800 may include a first base substrate 810, a first circuit layer 820, a first semiconductor device 830, a first molding part 870, a second circuit layer 851, a via 860, and an external connection terminal 880.

The first base substrate 810 may be generally any one of the substrates which are applied to the semiconductor package.

The first base substrate 810 may be provided with the first circuit layer 820. The first circuit layer 820 may include the first connection pad 821 and the second connection pad 822. Further, although not illustrated, the first circuit layer 820 may also include the circuit pattern (not illustrated). The first circuit layer 820 may be made of a conductive material. Further, the first semiconductor device 830 may be mounted on the first base substrate 810. The first semiconductor device 830 and the first base substrate 810 may be provided with a solder ball, a solder bump, a conductive adhesive, and a non-conductive adhesive. According to the preferred embodiment of the present invention, the first semiconductor device 830 is wire-bonded to the second connection pad 822.

The first molding part 870 is formed between the first base substrate 810 and the second circuit layer 851 to be able to protect the first circuit layer 820 and the first semiconductor device 830.

The second circuit layer 851 may be formed on the upper surface of the first molding part 870. The second circuit layer 851 may include the external connection pad.

The via 860 may be formed on the first circuit layer 820. A lower surface of the via 860 is bonded to the first connection pad 821 and an upper surface thereof is bonded to the second circuit layer 851. According to the preferred embodiment of the present invention, the via 860 may be formed so that the lower surface thereof has a diameter larger than that of the upper surface thereof. Although not illustrated, according to another preferred embodiment of the present invention, the via 860 is formed so that the upper surface thereof has a diameter larger than that of the lower surface thereof, thereby improving the matching degree with the via 860 and the second circuit layer 851. Further, the via 860 and the second circuit layer 851 may be integrally formed. FIG. 22 illustrates that the via 860 is formed in a straight shape, but the preferred embodiment of the present invention is not limited thereto. For example, the via 860 is bent once or more as illustrated in FIG. 14, such that the center of the upper surface thereof and the center of the lower surface thereof may be disposed on different vertical lines. Further, although not illustrated in the preferred embodiment of the present invention, the second circuit layer 851 may be disposed on the upper surface of the via 860 or on a vertical line at which the center of the second circuit layer 851 and the center of the lower surface of the via 860 are the same. In this case, even though the upper and lower surfaces of the via 860 are the same vertical line, a body of the via 860 may be variously bent, thereby improving the degree of freedom in design of components in the semiconductor package 800.

The external connection terminal 880 may be formed on the external connection pad of the second circuit layer 851. The first semiconductor package 800 may be electrically connected to the second semiconductor package 900 through the external connection terminal 880.

The first semiconductor package 800 illustrated in FIG. 22 is by way of example only, and therefore the structure of the first semiconductor package 800 is not limited thereto. That is, the first semiconductor package 800 has a structure in which the second circuit layer 851 and the via 860 are integrally formed and any of the preferred embodiments of the above-mentioned semiconductor packages may be applied.

The second semiconductor package 900 is formed on the first semiconductor package 800. The second semiconductor package 900 may include a second base substrate 910, a third circuit layer 920, a second semiconductor device 931, a third semiconductor device 932, and a second molding part 970.

The second base substrate 910 may be generally any one of the substrates which are applied to the semiconductor package. The second base substrate 910 may be provided with the third circuit layer 920. Further, the second semiconductor device 931 and the third semiconductor device 932 may be mounted on the second base substrate 910. According to the preferred embodiment of the present invention, the third semiconductor device 932 is stacked on the second semiconductor device 931. However, the number of semiconductor devices and the form in which the semiconductor device is mounted are not limited thereto. Further, the second semiconductor device 931 and the third semiconductor device 932 are connected to the third circuit layer 920 by the wire. However, a connection method between the second semiconductor device 931 and the third semiconductor device 932 and the third circuit layer 920 is not limited thereto.

The second molding part 970 may be formed to enclose the third circuit layer 920, the second semiconductor device 931, the third semiconductor device 932 which are formed on the second base substrate 910.

FIG. 22 illustrates that the second semiconductor package 900 has a structure different from the first semiconductor package 800. However, the second semiconductor package 900 may also be one of the preferred embodiments of the above-mentioned semiconductor packages.

According to the semiconductor package, the method of manufacturing a semiconductor package, and the stack type semiconductor package in accordance with the preferred embodiments of the present invention, it is possible to omit the laser machining process used to form the via hole by using the frame integrally formed with the via.

According to the semiconductor package, the method of manufacturing a semiconductor package, and the stack type semiconductor package in accordance with the preferred embodiments of the present invention, it is possible to save costs by simultaneously forming the plurality of vias in the frame.

According to the semiconductor package, the method of manufacturing a semiconductor package, and the stack type semiconductor package in accordance with the preferred embodiments of the present invention, it is possible to improve the degree of freedom in design of the circuit pattern by forming the via in various forms.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A semiconductor package, comprising:
a base substrate on which a first circuit layer is formed;
a semiconductor device formed on the base substrate;
a molding part formed on the base substrate and formed to enclose the first circuit layer and the semiconductor device;
a first via formed on the first circuit layer and formed to penetrate through the molding part; and
a second circuit layer formed on an upper surface of the molding part and integrally formed with the first via.

2. The semiconductor package as set forth in claim 1, wherein a lower surface of the first via has a diameter larger than that of an upper surface thereof.

3. The semiconductor package as set forth in claim 1, wherein a lower surface of the first via has a diameter smaller than that of an upper surface thereof.

4. The semiconductor package as set forth in claim 1, wherein the first via is bent once or more so that a center of the upper surface thereof and a center of the lower surface thereof are disposed on different vertical lines.

5. The semiconductor package as set forth in claim 1, wherein the first via is bent once or more so that a center of the upper surface thereof and a center of the lower surface thereof are disposed on the same vertical line.

6. The semiconductor package as set forth in claim 1, wherein the first via includes at least one of a conductive metal and a conductive resin.

7. The semiconductor package as set forth in claim 6, wherein an inside of the first via is made of a non-conductive resin.

8. The semiconductor package as set forth in claim 1, wherein an adhesive layer is further formed between the first via and the first circuit layer.

9. The semiconductor package as set forth in claim 1, wherein the adhesive layer includes at least one of a low-melting metal and a temporarily cured conductive epoxy resin.

10. The semiconductor package as set forth in claim 1, wherein the semiconductor device is connected to the first circuit layer by a wire.

11. The semiconductor package as set forth in claim 1, further comprising:
a second via of which the lower surface is connected to the semiconductor device and the upper surface is connected to the second circuit layer.

12. The semiconductor package as set forth in claim 11, wherein the second circuit layer electrically connects the first via to the second via.

13. The semiconductor package as set forth in claim 12, wherein the second via is made of the same material as the first via.

14. The semiconductor package as set forth in claim 1, further comprising:
an external connection terminal formed on the second circuit layer.

15. A method of manufacturing a semiconductor package, comprising:
preparing a base substrate on which a first circuit layer and a semiconductor device are formed;
preparing a frame having a lower surface provided with a first via;
mounting the frame on the base substrate;
forming a molding part by injecting a molding material between the base substrate and the frame; and
forming a second circuit layer by patterning the frame.

16. The method as set forth in claim 15, wherein the preparing of the frame having the lower surface provided with the first via includes:
preparing the frame; and
forming the first via on the frame by injecting a conductive resin into the frame by a screen printing method or an injection molding method.

17. The method as set forth in claim 15, wherein the preparing of the frame having the lower surface provided with the first via includes:
preparing the frame;
forming an inside of the first via on the frame by injecting a non-conductive resin into the frame by a screen printing method or an injection molding method; and
forming the first via by plating a conductive material to the inside of the first via.

18. The method as set forth in claim 15, wherein the preparing of the frame having the lower surface provided with the first via includes:
preparing the frame; and
forming the first via by providing plastic deformation of one side of the frame with a press mold.

19. The method as set forth in claim 18, wherein the number of frames is plural.

20. The method as set forth in claim 15, wherein a lower surface of the first via has a diameter larger than that of an upper surface thereof.

21. The method as set forth in claim 15, wherein a lower surface of the first via has a diameter smaller than that of an upper surface thereof.

22. The method as set forth in claim 15, wherein the first via is bent once or more so that a center of the upper surface thereof and a center of the lower surface thereof are disposed on different vertical lines.

23. The method as set forth in claim 15, wherein the first via is bent once or more so that a center of the upper surface thereof and a center of the lower surface thereof are disposed on the same vertical line.

24. The method as set forth in claim 15, wherein the preparing of the frame having the lower surface provided with the first via further includes applying an adhesive on a lower surface of the first via.

25. The method as set forth in claim 24, wherein the adhesive includes at least one of a low-melting metal and a temporarily cured conductive epoxy.

26. The method as set forth in claim 15, wherein the semiconductor device is connected to the first circuit layer by a wire.

27. The method as set forth in claim 15, wherein the preparing of the frame having the lower surface provided with the first via further includes forming a second via connected to the semiconductor device.

28. The method as set forth in claim 27, wherein the second via is formed by the same material and method as the first via.

29. The method as set forth in claim 27, wherein the second circuit layer electrically connects the first via to the second via.

30. The method as set forth in claim 15, further comprising:
after the forming of the second circuit layer,
forming an external connection terminal to the second circuit layer.

31. A stack type semiconductor package, comprising:
a first semiconductor package which includes a base substrate on which a first circuit layer and a first semiconductor device are formed, a molding part formed on the base substrate and formed to enclose the first circuit layer and the first semiconductor device, a first via formed on the first circuit layer and formed to penetrate through the molding part, and a second circuit layer formed on an upper surface of the molding part and integrally formed with the first via; and
a second semiconductor package formed on the first semiconductor package and including a second semiconductor device;

32. The stack type semiconductor package as set forth in claim 31, wherein a lower surface of the first via has a diameter larger than that of an upper surface thereof.

33. The stack type semiconductor package as set forth in claim 31, wherein a lower surface of the first via has a diameter smaller than that of an upper surface thereof.

34. The stack type semiconductor package as set forth in claim 31, wherein the first via is bent once or more so that a center of the upper surface thereof and a center of the lower surface thereof are disposed on different vertical lines.

35. The stack type semiconductor package as set forth in claim 31, wherein the first via is bent once or more so that a center of the upper surface thereof and a center of the lower surface thereof are disposed on the same vertical line.

36. The stack type semiconductor package as set forth in claim 31, wherein the first semiconductor package is connected to the second semiconductor package by an external connection terminal.
